(19) United States
(12) Patent Application Publication
(10) Pub. No.: US 2026/0011658 A1
(43) Pub. Date: Jan. 8, 2026

(54) Multi-Die Packaging Structure

(71) Applicant: Joulwatt Technology Co., Ltd., Hangzhou City (CN)

(72) Inventors: Jia CHEN, Hangzhou (CN); Yajun ZHU, Hangzhou (CN)

(21) Appl. No.: 19/257,527

(22) Filed: Jul. 2, 2025

(30) Foreign Application Priority Data
Jul. 5, 2024 (CN) 202410902710.7
Jul. 5, 2024 (CN) 202410903708.1
Jul. 5, 2024 (CN) 202410903935.4

(51) Int. Cl. H01L 23/58

(52) U.S. Cl. CPC H01L 23/58

(57) ABSTRACT

A multi-die packaging structure includes: a first die, comprising at least a second conductive layer; a second core; and an isolation structure, located on the first die and electrically connected to the second die, wherein the isolation structure comprises: an insulating dielectric layer; the first conductive layer located above the insulating dielectric layer; and an adhesive layer located below the insulating dielectric layer, the first conductive layer in the isolation structure and the second conductive layers in the first die forms at least one of the isolation inductance, isolation capacitor, and isolation transformer. By setting an isolation structure electrically connected to the second die on the first die, the first conductive layer in the isolation structure is separated from the second conductive layer in the first die by an insulating dielectric layer in the isolation structure.

### CROSS-REFERENCE TO RELATED APPLICATIONS

This present disclosure claims priority to a Chinese patent application No. 2024109037081, filed on Jul. 5, 2024, and entitled “multi-die packaging structure and chip thereof”, a Chinese patent application No. 2024109039354, filed on Jul. 5, 2024, and entitled “electrical isolation structure and manufacturing method thereof and multi-die packaging structure”, and a Chinese patent application No. 2024109027107, filed on Jul. 5, 2024, and entitled “electrical isolation structure and manufacturing method thereof and multi-die packaging structure”, the entire contents of which are incorporated herein by reference, including the specification, claims, drawings and abstract.

### FIELD OF TECHNOLOGY

This disclosure relates to the field of semiconductor device technology, more particularly, to a multi-die packaging structure.

### BACKGROUND

Multi-die packaging is a kind of packaging technology for integrated circuits; in multiple dies, each die contains specific functional modules or partial circuits. These dies can be independently manufactured and then combined together during the packaging process to form a complete chip.

In multi-die packaging, it needs to isolate the high voltage die from the low voltage die in order to improve the stability and safety of the circuit. Common high and low voltage isolation techniques mainly include magnetic isolation, capacitive isolation, and inductive isolation. For example, two dies made of silicon substrates are packaged, and the two stacked dies are connected through organic materials; the conductive layer in the two dies forms an isolator with the organic material, thereby achieving high and low voltage isolation. However, the silicon substrate located between two conductive layers is semiconductor material rather than insulating material, so the coupling performance of the isolator is poor. Moreover, due to the difficulty in controlling the thickness uniformity of organic materials and the tendency to form holes, the overall voltage resistance performance of the isolator and stacked die is not stable.

Therefore, a new multi-die packaging structure needs to be proposed to solve the above problems.

### SUMMARY OF THE DISCLOSURE

In view of the above issues, the objective of this disclosure is to provide a multi-die packaging structure, which is electrically connected to a second die by setting an isolation structure on a first die. The first conductive layer in the isolation structure is separated from the second conductive layer in the first die by an insulating dielectric layer in the isolation structure, which not only meets the connection and isolation requirements between the plural dies, but also improves the isolation and voltage resistance performance of each die.

According to one aspect of the present invention, a multi-die packaging structure is provided, comprising:
a first die, comprising at least a second conductive layer;
a second die; and
an isolation structure, located on the first die and electrically connected to the second die,
wherein the isolation structure comprises:
an insulation dielectric layer;
a first conductive layer located above the insulating dielectric layer; and
an adhesive layer located below the insulating dielectric layer,
at least one of the first conductive layer in the isolation structure and the second conductive layer in the first die forms at least one of an isolation inductor, isolation capacitor, or an isolation transformer.

Optionally, the first die is one of high voltage die and low voltage die, wherein the second die is the other one of the high voltage die and the low voltage die, and the isolation structure is for improving the voltage resistance performance of the first die and the second die.

Optionally, the second conductive layer is the top metal layer of the first die or multiple conductive stacks in the first die.

Optionally, the first chip further comprises a semiconductor layer, and the second conductive layer is located above the semiconductor layer.

Optionally, materials of the insulating dielectric layer comprises at least one of glass, pre-impregnated resin glass fiber cloth, and adhesive film.

Optionally, the isolation structure further comprises a connection layer located between the insulating dielectric layer and the first conductive layer, for fixedly connecting the insulating dielectric layer and the first conductive layer.

Optionally, material of the connecting layer comprises a titanium compound; the first conductive layer is a metal plating layer, and the connecting layer is a seed layer of the metal plating layer.

Optionally, the first conductive layer is a single-layer conductive layer or multiple conductive stacked layers.

Optionally, the isolation structure further comprises an interlayer isolation layer and an interlayer connection layer,
in the first conductive layer, the interlayer isolation layer and the interlayer connection layer are located between two adjacent conductive stacks.

Optionally, the isolation structure further comprises a metal coating layer located on the surface of the first conductive layer.

Optionally, material of the adhesive layer comprises at least one of mounting adhesive, polyimide, and pre-impregnated resin glass fiber cloth, and the isolation structure is fixed to the first die through the adhesive layer.

According to a second aspect of the present invention, there is provided a multi-die packaging structure, comprising: a first die, a second die, and an isolation structure, wherein the isolation structure is electrically connected to the first die and the second die, respectively,
the isolation structure comprises a first isolation structure, a second isolation structure, and an adhesive layer located between the first isolation structure and the second isolation structure,
wherein the first isolation structure comprises:
a first glass substrate;
a first connecting layer, located on the first glass substrate; and
a first conductive layer, located on the first connection layer,
the second isolation structure comprises:
a second glass substrate;
a second connecting layer, located on the second glass substrate; and
a second conductive layer, located on the second connection layer,
the adhesive layer is located between the first glass substrate and the second conductive layer, and is used to fixedly connect the first isolation structure and the second isolation structure,
at least one of the first conductive layer and the second conductive layer forms at least one of an isolation inductor, isolation capacitor, or isolation transformer.

Optionally, the first conductive layer is a single-layer conductive layer or multiple conductive stacks, and the second conductive layer is a single-layer conductive layer or multiple conductive stacks.

Optionally, an interlayer dielectric layer and an interlayer connection layer are located between two adjacent conductive stacks.

According to the third aspect of the present disclosure, there is provided a multi-die packaging structure, comprising:
a first die, a second die, and an isolation structure, wherein the isolation structure is electrically connected to the first die and the second die, respectively,
the isolation structure comprises:
a glass substrate, with opposing first surface and second surface;
a first connecting layer, located on the first surface;
a second connecting layer, located on the second surface;
a first conductive layer, located on the first connection layer; and
a second conductive layer located on the second connection layer,
wherein, at least one of the first conductive layer and the second conductive layer forms at least one of an isolation inductor, isolation capacitor, or isolation transformer.

Optionally, the first conductive layer is a single-layer conductive layer or multiple conductive stacks, and the second conductive layer is a single-layer conductive layer or multiple conductive stacks.

Optionally, the interlayer dielectric layer and the interlayer connection layer are located between the two adjacent conductive stacks.

Optionally, it further comprises a packaging frame, wherein the first die and the second die are respectively fixed on the packaging frame.

Optionally, a solder pad on the packaging structure are electrically connected to the first conductive layer of the isolation structure through wire bonding, or the second die comprises a third conductive layer, which is electrically connected to the first conductive layer of the isolation structure through wire bonding.

Optionally, it further comprises a packaging layer for covering the first die, the second die, and the isolation structure.

According to the other aspect of the present disclosure, there is provided a chip comprising the above multi-die packaging structure.

The first technical solution in the above technical solutions has the following advantageous effects:

By setting an isolation structure on the first die and electrically connecting it to the second die, the first conductive layer and insulating dielectric layer in the isolation structure form an isolation structure with the second conductive layer in the first die, such as forming at least one of an isolation inductor, isolation capacitor, or isolation transformer, thus meeting the requirements of connection and signal isolation transmission between the first die and the second die. Meanwhile, the first conductive layer and the second conductive layer are separated by an insulating dielectric layer in the isolation structure. Compared with the solution of stacking and packaging two dies made of silicon substrates, using an insulating dielectric layer can improve the coupling performance of the isolator and the overall voltage resistance of the first and second dies. Furthermore, in the isolation structure, an adhesive layer is provided below the insulating dielectric layer, and the isolation structure is bonded and fixed to the first die through the adhesive layer. That is to say, the first die and the isolation structure can be manufactured separately, reducing the manufacturing difficulty of the first die and the isolation structure and improving the yield.

In some embodiments, by reusing the top metal layer or multiple conductive stacks in the first die as one of the conductive layers (second conductive layer) that make up the isolator, it can greatly save materials and reduce production processes.

In some embodiments, the insulating dielectric layer for isolating the first conductive layer from the second conductive layer is composed of glass. Glass is hard and its uniformity of thickness is easy to control, making it less prone to holes and thus improving the overall voltage resistance of the packaging structure. In addition, the price of glass is relatively cheap, which can reduce the manufacturing cost of packaging structures and its chips.

In some embodiments, the insulating dielectric layer used to isolate the first conductive layer from the second conductive layer is composed of pre-impregnated resin glass fiber cloth material or adhesive films, wherein the pressure resistance of the pre-impregnated resin glass fiber cloth material can reach 160V/μm, greatly enhancing the overall pressure resistance performance of the sealing structure. In addition, due to the use of pre-impregnated resin glass fiber cloth and adhesive films, the material has good toughness and is not easily broken, thereby improving the yield and service life of the packaging structure and its chips.

It should be noted that the above general description and the detailed description in the following text are only exemplary and explanatory, and cannot limit this disclosure.

### BRIEF DESCRIPTION OF THE DRAWINGS

The above and other objectives, features, and advantages of the present disclosure will become clearer through the following description of the embodiments of the present disclosure with reference to the accompanying drawings.

FIG. 1 shows a structural schematic diagram of the multi-die packaging structure in the related technology;

FIG. 2 shows a structural schematic diagram of the isolation structure of the first embodiment of the present disclosure;

FIG. 3 shows a structural schematic diagram of the first die of the first embodiment of the present disclosure;

FIG. 4 shows a structural schematic diagram after the isolation structure and the first die in the first embodiment of the present disclosure are fixed;

FIG. 5 shows a structural schematic diagram of the first packaging manner of the multi-die packaging structure in the first embodiment of the present disclosure;

FIG. 6 shows a structural schematic diagram of the second packaging manner of the multi-die packaging structure in the first embodiment of the present disclosure;

FIG. 7 shows a structural schematic diagram of the isolation structure of the second embodiment of the present disclosure;

FIG. 8A shows a structural schematic diagram of the isolation structure of the third embodiment of the present disclosure;

FIG. 8B shows a structural schematic diagram after the isolation structure and the first die in the third embodiment of the present disclosure are fixed;

FIG. 9A shows a structural schematic diagram of the isolation structure in the fourth embodiment of the present disclosure;

FIG. 9B shows a structural schematic diagram after the isolation structure and the first die in the fourth embodiment of the present disclosure are fixed.

### DETAILED DESCRIPTION OF THE DISCLOSURE

Various embodiments of the present disclosure will be described in more detail below with reference to the accompanying drawings. In each accompanying drawing, the same elements or modules are represented by the same or similar reference numerals. For clarity, the various parts in the accompanying drawings are not drawn to scale.

The present disclosure will be described in more detail below with reference to the accompanying drawings. In each drawing, the same elements are represented by similar reference numerals. For clarity, the various parts in the accompanying drawings are not drawn to scale. In addition, some well-known parts may not be shown. For the sake of simplicity, the semiconductor structure obtained after several steps can be described in one drawing.

It should be understood that when describing the structure of a device, when referring to a layer or region as being located “above” or “on” another layer or region, it means that it is directly located above another layer or region, or containing other layers or regions between it and another layer or region. And, if the device is flipped over, that layer or region will be located “below” or “under” another layer or region.

If in order to describe the situation of being directly located on another layer or area, this text will use expressions such as “directly on . . . ” or “on . . . and adjacent to it”.

The following text describes many specific details of the present disclosure, such as the structure, materials, dimensions, processing techniques, and technologies of the device, so as to better understand the present disclosure. But as those skilled in the art can understand, this disclosure may not be implemented according to these specific details.

Meanwhile, certain terms are used in the specification and claims of the present patent to refer to specific components. Those of ordinary skill in the art should understand that hardware manufacturers may use different terms to refer to the same component. The specification and claims of the present patent do not use differences in names as a way to distinguish components, but rather use differences in functionality of components as a criterion for differentiation.

In addition, it should be noted that in this text, relational terms such as first and second are only used to distinguish one entity or operation from another, and do not necessarily require or imply any actual relationship or order between these entities or operations. Moreover, terms of “including”, “comprising”, or any other variation thereof are intended to encompass non-exclusive inclusion, such that a process, method, item, or device that includes a series of elements includes not only those elements, but also other elements not explicitly listed, or elements inherent to such process, method, item, or device. Without further restriction, the element defined by the statement “including one . . . ” does not exclude the existence of other identical elements in the process, method, item, or device that includes the element in question.

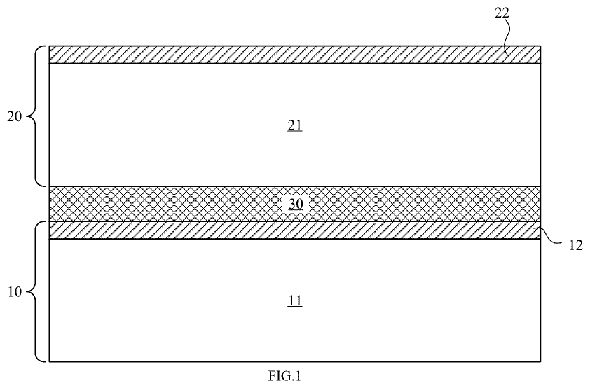

FIG. 1 shows a structural schematic diagram of the multi-die packaging structure in the related technology.

As shown in FIG. 1, in the related technology, the multi-die packaging structure comprises a first die 10, a second die 20, and a dielectric layer 30. The first die 10 comprises a silicon substrate 11 and an FAB top layer metal 12 located on the silicon substrate 11. The second die 20 comprises a silicon substrate 21 and an FAB top layer metal 22 located on the silicon substrate 21, wherein the FAB top layer metal is a metal layer added in the final stage of the die manufacturing process. Die is the pre-packaged grain of a chip, which is a small piece cut from a wafer.

The first die 10 and the second die 20 are stacked and packaged, with the dielectric layer 30 located between the top metal layer 12 of FAB and the silicon substrate 21, for fixedly connect the stacked first die 10 and second die 20. The material of dielectric layer 30 is pre-impregnated resin glass fiber cloth (prepreg, PP), which is an organic insulation material used as the electrical isolation medium between FAB top metal 12 and FAB top metal 22.

Refer to FIG. 1, between the FAB top metal 12 and FAB top metal 22, besides the electrical isolation medium composed of PP material, there is also a silicon substrate 21. The thickness of the silicon substrate 21 increases the distance between the FAB top metal 12 and FAB top metal 22, and the silicon substrate 21, which is a semiconductor material, also conducts electricity, resulting in poor coupling performance of the isolator. In addition, as PP material is an organic material, its thickness uniformity is difficult to control and it is easy to form pores. Assume that the voltage resistance of the isolator needs to reach 3000V, the pores or process impurities in the PP material can easily cause breakdown in this area, resulting in unstable overall voltage resistance performance of the isolator.

In view of the above issues, the purpose of the present disclosure is to provide a multi-die packaging structure, which is electrically connected to a second die by setting an isolation structure on a first die. The first conductive layer in the isolation structure is separated from the second conductive layer in the first die by an insulating dielectric layer in the isolation structure, which not only meets the connection and isolation requirements between the multiple dies, but also improves the voltage resistance performance of each die.

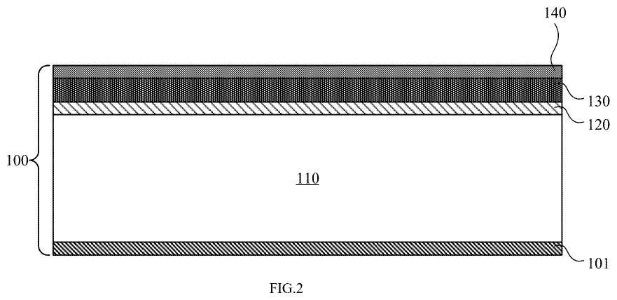

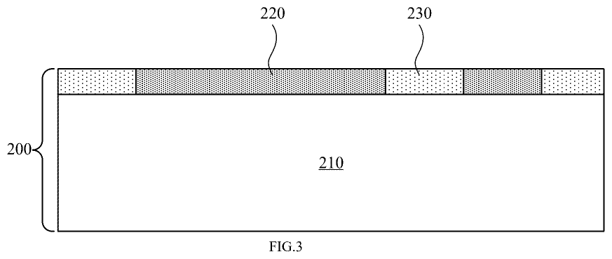

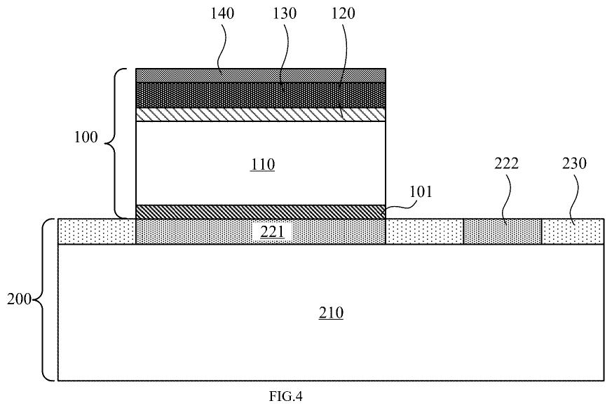

FIG. 2 shows a structural schematic diagram of the isolation structure of the first embodiment of the present disclosure; FIG. 3 shows a structure schematic diagram of the structure of the first die of the first embodiment of the present disclosure; FIG. 4 shows a structural schematic diagram after the isolation structure and the first die in the first embodiment of the present disclosure are fixed.

As shown in FIGS. 2 to 4, in this embodiment, the isolation structure 100 comprises an insulating dielectric layer 110, a connection layer 120, a first conductive layer 130, and a metal coating layer 140. Along the thickness direction of the insulating dielectric layer 110, the connecting layer 120, the first conductive layer 130, and the metal coating layer 140 are sequentially stacked on the first surface of the insulating dielectric layer 110. The isolation structure 100 further comprises an adhesive layer 101 located on the second surface of the insulating dielectric layer 110, wherein the first surface of the insulating dielectric layer 110 is opposite to the second surface. The material of the insulating dielectric layer 110 comprises at least one of glass, pre-impregnated resin glass fiber cloth (PP), and adhesive bonding film (ABF), and the ABF is typically made of polyimide and/or other high-temperature adhesives. Materials of the connection layer 120 include titanium compounds such as TiW, TiCu, etc. The first conductive layer 130 is a metal layer, such as Cu, Al, Ag, etc. Materials of adhesive layer 101 include at least one of insulating mounting adhesive, polyimide, and pre-impregnated resin glass fiber cloth.

In the manufacturing process of the isolation structure 100, the connection layer 120 is formed on the first surface of the insulating dielectric layer 110 through a deposition process, and then the first conductive layer 130 is formed on the connection layer 120 through an electroplating process, wherein since metal materials are not easy to directly adhere to glass, PP, and ABF materials, the connection layer 120 serves as a seed layer for electroplating the first conductive layer 130, assisting the first conductive layer 130 of the metal material to be fixedly connected to the insulating dielectric layer 110 of glass, PP, and ABF materials.

The metal coating layer 140 is made of materials such as Ni, Au, etc. When the material of the first conductive layer 130 is Cu, since Cu is very hard, it is not conducive to the subsequent wire bonding process. Therefore, it needs to form the metal coating layer 140 on the surface of the first conductive layer 130. If the material of the first conductive layer 130 is Al which is relatively soft, the metal coating layer 140 can also be omitted.

However, embodiments of the present disclosure are not limited to this, and those skilled in the art may make other settings for the materials of the connection layer 120, the first conductive layer 130, the adhesive layer 101, and the metal coating layer 140 as needed.

As shown in FIGS. 3 and 4, the first die 200 comprises a semiconductor layer 210, a second conductive layer 221 located on the semiconductor layer 210, a solder pad 222, and an isolation layer 230. Wherein, the semiconductor layer 210 is a stacked structure composed of Si, SiC substrate or substrate and epitaxial layer, which is formed by doping and other processes such as CMOS circuit. The second conductive layer 221 can be FAB top metal layer, or multiple conductive stacked layers located on the semiconductor layer 210. The materials of the multiple conductive layers can be metal or polycrystalline silicon, etc. The multiple conductive layers are separated by an isolation layer 230, which is made of materials such as silicon oxide, silicon nitride, etc.

In some optional embodiments, the adhesive layer 101 is attached to the second surface of the insulating dielectric layer 110, and the adhesive layer 101 is covered by a protective film. When it is fixedly connected to the first die 200, the protective film can be removed, and the isolation structure 100 is fixed to the first die 200 through the adhesive layer 101, so as to fixedly connect the insulation medium layer 110 in the isolation structure 100 with the second conductive layer 221 in the first die 200 through the adhesive layer 101.

In some alternative embodiments, the adhesive layer 101 can also be attached to the surface of the second conductive layer 221, and a protective film can be covered on top of the adhesive layer 101. After the protective film is removed, the isolation structure 100 can be attached and fixed to the first die 200.

As shown in FIG. 4, after the isolation structure 100 is fixed to the first die 200 through the adhesive layer 101, the first conductive layer 130, insulating dielectric layer 110 in the isolation structure 100, and the second conductive layer 221 in the first die 200 form an isolator, wherein the first conductive layer 130 and the second conductive layer 221 are electrically isolated through the insulating dielectric layer 110. At least one of the first conductive layer 130 and the second conductive layer 221 forms at least one of an isolation inductor, isolation capacitor, or isolation transformer. In some specific embodiments, the first conductive layer 130 and the second conductive layer 221 are respectively two plates of the isolation capacitor, or the first conductive layer 130 and the second conductive layer 221 are respectively two inductance coils of the isolation transformer.

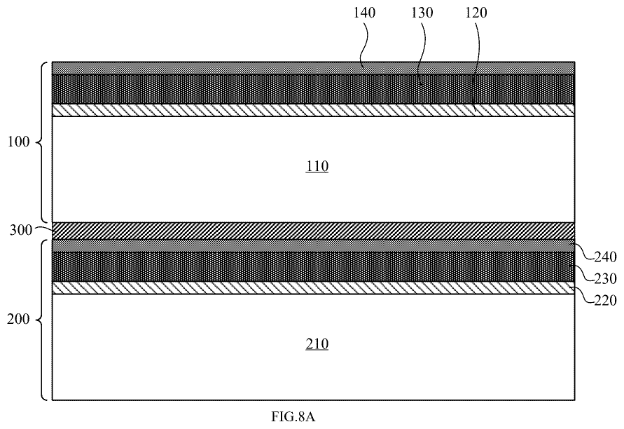

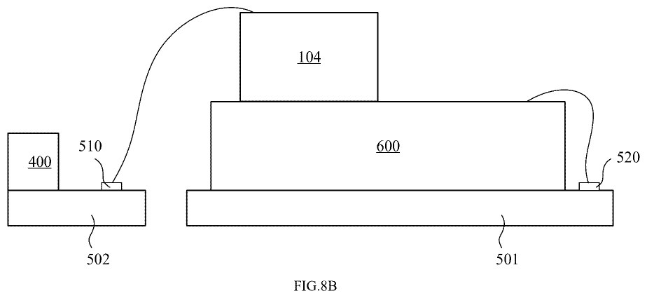

In another example, as shown in FIGS. 8A and 8B, the isolation structure 104 comprises a first isolation structure 100, a second isolation structure 200, and an adhesive layer 300, wherein the adhesive layer 300 is located between the first isolation structure 100 and the second isolation structure 200, and is used to fixedly connect the first isolation structure 100 and the second isolation structure 200.

The first isolation structure 100 comprises a first glass substrate 110, a first connection layer 120, a first conductive layer 130, and a first metal coating layer 140, wherein the first connection layer 120, the first conductive layer 130, and the first metal coating layer 140 are sequentially stacked on the same surface of the first glass substrate 110 along the thickness direction of the first glass substrate 110. The second isolation structure 200 comprises a second glass substrate 210, a second connection layer 220, a second conductive layer 230, and a second metal coating layer 240, wherein the second connection layer 220, the second conductive layer 230, and the second metal coating layer 240 are sequentially stacked on the same surface of the second glass substrate 210 along the thickness direction of the second glass substrate 210. The first glass substrate 110 and the second metal coating layer 240 are fixedly connected through an adhesive layer 300.

The first conductive layer 130, the first glass substrate 110, and the second conductive layer 230 in the isolation structure 104 constitute an isolator, wherein the first conductive layer 130 and the second conductive layer 230 are electrically isolated by the first glass substrate 110. At least one of the first conductive layer 130 and the second conductive layer 230 forms at least one of the isolation inductor, isolation capacitor, or isolation transformer. In some specific embodiments, the first conductive layer 130 and the second conductive layer 230 are respectively two plates of the isolation capacitor, or the first conductive layer 130 and the second conductive layer 230 are respectively two inductance coils of the isolation transformer.

Materials of the adhesive layer 300 include at least one of insulating mounting adhesive, polyimide, and pre-impregnated resin glass fiber cloth. Materials of the first connection layer 120 and the second connection layer 220 include titanium compounds, such as TiW, TiCu, etc. Materials of the first conductive layer 130 and the second conductive layer 230 are metals such as Cu, Al, Ag, etc. Materials of the first metal coating layer 140 and the second metal coating layer 240 are, e.g., Ni, Au, etc. Wherein, when the material of the first conductive layer 130 and the second conductive layer 230 is Cu, since Cu is very hard, it is not conducive to the subsequent wire bonding process. Therefore, it is necessary to form a metal coating layer on the surface of the first conductive layer 130 and the second conductive layer 230. If the material of the first conductive layer 130 and the second conductive layer 230 is Al which is soft, a metal coating layer can also be omitted.

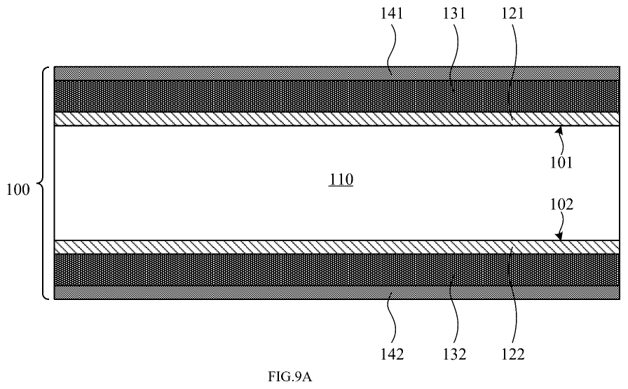

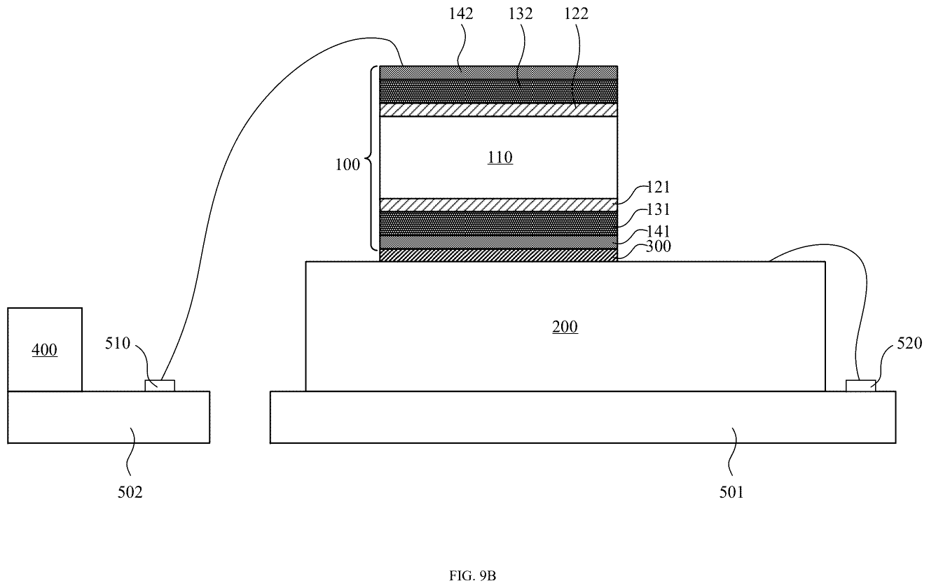

In other examples, as shown in FIGS. 9A and 9B, the isolation structure 100 comprises a glass substrate 110, a first connection layer 121, a second connection layer 122, a first conductive layer 131, a second conductive layer 132, a first metal coating layer 141, and a second metal coating layer 142.

The glass substrate 110 has two opposing surfaces, namely a first surface 101 and a second surface 102. Along the direction of the second surface 102 towards the first surface 101, the first connection layer 121, the first conductive layer 131, and the first metal coating layer 141 are sequentially stacked on the first surface 101 of the glass substrate 110. Along the direction of the first surface 101 towards the second surface 102, the second connection layer 122, the second conductive layer 132, and the second metal coating layer 142 are sequentially stacked on the second surface 102 of the glass substrate 110.

The first conductive layer 131, the glass substrate 110, and the second conductive layer 132 in isolation structure 100 constitute an isolator, wherein the first conductive layer 131 and the second conductive layer 132 are electrically isolated by the glass substrate 110. At least one of the first conductive layer 131 and the second conductive layer 132 forms at least one of an isolation inductor, isolation capacitor, or isolation transformer. In some specific embodiments, the first conductive layer 131 and the second conductive layer 132 are respectively two plates of the isolation capacitor, or the first conductive layer 131 and the second conductive layer 132 are respectively two inductance coils of the isolation transformer.

Materials of the first connection layer 121 and the second connection layer 122 include titanium compounds such as TiW, TiCu, etc. Materials of the first conductive layer 131 and the second conductive layer 132 are metals such as Cu, Al, Ag, etc. Materials of the first metal coating layer 141 and the second metal coating layer 142 are, e.g., Ni, Au, etc. Wherein, when the material of the first conductive layer 131 and the second conductive layer 132 is Cu, since Cu is very hard, it is not conducive to the subsequent wire bonding process. Therefore, it needs to form a metal coating layer on the surfaces of the first conductive layer 131 and the second conductive layer 132. If the material of the first conductive layer 131 and the second conductive layer 132 is Al which is soft, a metal coating layer can also be omitted.

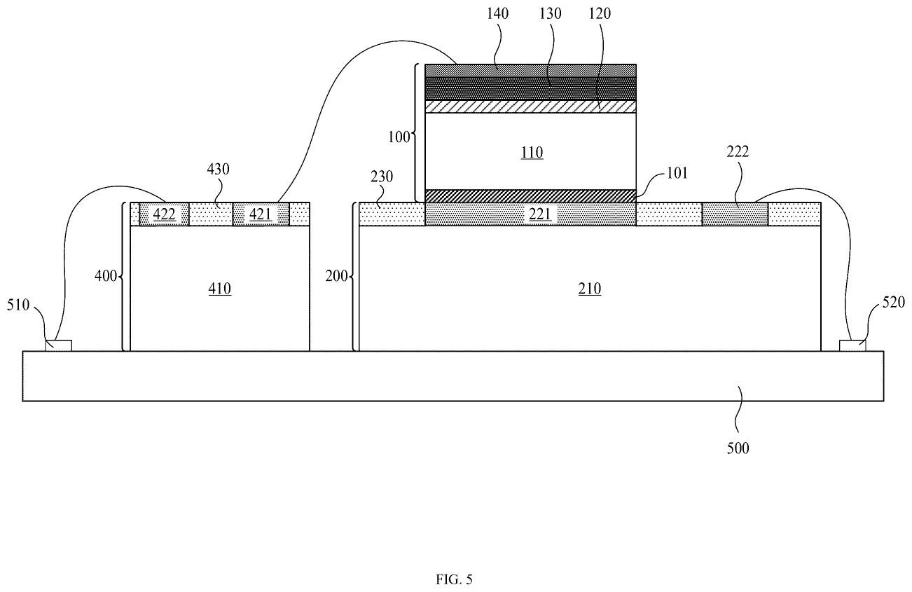

FIG. 5 shows a structural schematic diagram of the first packaging method of the multi-die packaging structure in the first embodiment of the present disclosure.

As shown in FIG. 5, the multi-die packaging structure of the first embodiment of the present disclosure comprises an isolation structure 100, a first die 200, a second die 400, a packaging frame 500, and a packaging layer (not shown). Wherein, the second die 400 comprises a semiconductor layer 410 and a third conductive layer 421, a pad 422, and an isolation layer 430 located on the semiconductor layer 410. The third conductive layer 421 and the pad 422 are the FAB top metal of the second die 400. Solder pads 510 and 520 are set on the packaging frame 500. The first die 200 carries the isolation structure 100, and the first die 200 and the second die 400 are respectively located on the packaging frame 500. The metal coating layer 140 is connected to the third conductive layer 421, the solder pad 422 is connected to the solder pad 510, and the solder pad 222 is connected to the solder pad 520 through wire bonding processes. The packaging layer is used to cover the first die 200, the second die 400, and the isolation structure 100.

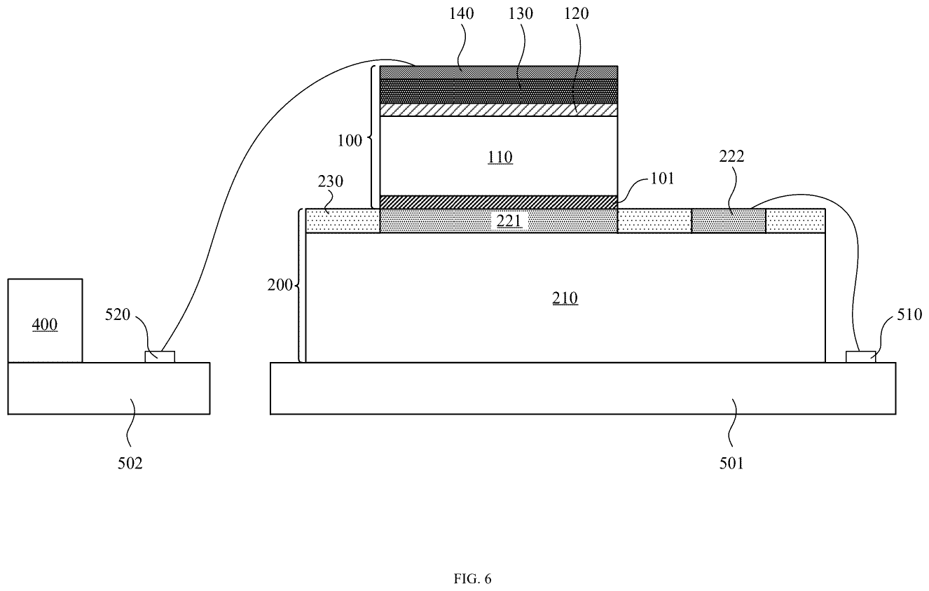

FIG. 6 shows a schematic diagram of the second packaging method of the multi-die packaging structure in the first embodiment of the present disclosure.

As shown in FIG. 6, for the similarities with the first packaging method, they are not repeated. The difference lies in that the packaging framework of the second packaging method comprises a first packaging framework 501 and a second packaging framework 502. The first die 200 carries the isolation structure 100, and is located on the packaging frame 501. The solder pad 222 is connected to the solder pad 510 on the packaging frame 501 through wire bonding. The second die 400 is located on the packaging frame 502, and is electrically connected to the solder pad 520 through the wiring on the packaging frame 502. The solder pad 520 on the packaging frame 502 is connected to the metal coating layer 140 of the isolation structure 100 through wire bonding.

The present disclosure also provides a chip with a multi-die packaging structure as shown in FIGS. 5 and 6. The high and low voltage isolation circuit of the chip is usually composed of a transmitting end, a receiving end, and an isolator. The transmitting end is composed of a circuit in the first chip 200, and the receiving end is composed of a circuit in the second chip 400, wherein the first chip 200 is one of the high voltage and low voltage chips, and the second chip 400 is the other of the high voltage and low voltage chips. Here the types of the first chip 200 and the second chip 400 are not limited, and those skilled in the art can set them according to the specific requirements of the circuit function.

However, the disclosed embodiment is not limited to this, and those skilled in the art may make other settings for the connection between the lead frame, the first die 200, and the second die 400 as needed.

In this embodiment, the first conductive layer 130 and the second conductive layer 221 are directly electrically isolated through the insulating dielectric layer 110. Compared with the situation where there is a semiconductor material such as a silicon substrate between the two conductive layers, directly achieving electrical isolation between the two conductive layers through the insulating dielectric layer 110 can greatly improve the coupling performance of the isolator.

The withstand voltage level of glass material can reach 35V/μm, and the insulation layer 110 of glass is hard and the uniformity of thickness is easy to control, making it less prone to holes. Therefore, it can improve the overall withstand voltage performance of the isolator, and thus enhance the withstand voltage performance of the first die 200 and the second die 400 respectively connected to the isolator. In addition, the price of glass is relatively cheap, which can reduce the manufacturing cost of multi-die packaging structures.

The insulation dielectric layer 110 of pre-impregnated resin glass fiber cloth material can achieve a withstand voltage of 160V/μm, greatly enhancing the overall withstand voltage performance of the isolator, and thereby improving the withstand voltage performance of the first die 200 and the second die 400 respectively connected to the isolator. In addition, due to the use of pre-impregnated resin glass fiber cloth and adhesive film, the material has good toughness and is not easily broken, thereby improving the yield and service life of the multi-die packaging structure.

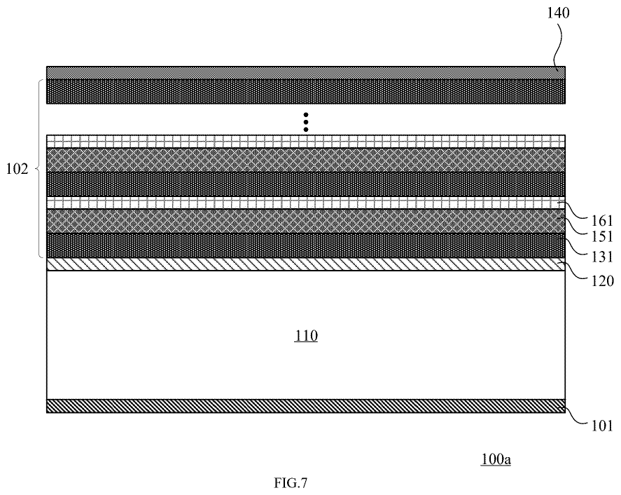

FIG. 7 shows a structural schematic diagram of the isolation structure of the second embodiment of the present disclosure.

As shown in FIG. 7, the similarities between the isolation structure 101 of the second embodiment of the present disclosure and the isolation structure 100 of the first embodiment will not be repeated. The difference is that the stacked structure 102 of the isolation structure 101 is located on the connection layer 120, and the stacked structure 102 is composed of alternately stacked conductive layers 131, interlayer isolation layers 151, and interlayer connection layers 161. The top layer of the stacked structure 102 is the conductive layer 131. The metal coating layer 140 is located on the surface of the top conductive layer 131 of the stacked structure 102. Wherein, the conductive layer 131 is made of metal materials such as Cu, Al, Ag, etc., the interlayer isolation layer 151 is made of PP material, ABF material, etc., and the interlayer connection layer 161 is made of titanium compounds such as TiCu, TiW, etc. The multiple conductive layers 131 stacked in the stacked structure 102 of this embodiment can replace the first conductive layer 130 of the first embodiment, or the first conductive layer 130 comprises multiple conductive layers, which serve as one of the plates of the isolation capacitor or one of the inductance coils of the isolation transformer.

According to the embodiments disclosed herein, such as those mentioned above, not all details are described in detail, nor are they limited to the specific embodiments of the invention. Obviously, based on the above description, many modifications and changes can be made. This specification selects and specifically describes these embodiments in order to better explain the principles and practical applications of this disclosure, so that those skilled in the art can make good use of this disclosure and make modifications based on it. The protection scope of this disclosure shall be subject to the scope defined by the claims and their equivalents of this disclosure.

The above implementation methods do not constitute a limitation on the protection scope of the technical solution. Any modifications, equivalent substitutions, and improvements made within the spirit and principles of the above implementation shall be included within the scope of protection of the technical solution.

What is claimed is:

1. A multi-die packaging structure, comprising:
a first die, comprising at least a second conductive layer;
a second die; and
an isolation structure, located on the first die and electrically connected to the second die,
wherein the isolation structure comprises:
an insulation dielectric layer;
a first conductive layer located above the insulating dielectric layer; and
an adhesive layer located below the insulating dielectric layer,
at least one of the first conductive layer in the isolation structure and the second conductive layer in the first die forms at least one of an isolation inductor, isolation capacitor, or an isolation transformer.

2. The multi-die packaging structure of claim 1, wherein the first die is one of high voltage die and low voltage die, wherein the second die is the other one of the high voltage die and the low voltage die, and the isolation structure is for improving the voltage resistance performance of the first die and the second die.

3. The multi-die packaging structure of claim 1, wherein the second conductive layer is the top metal layer of the first die or multiple conductive stacks in the first die.

4. The multi-die packaging structure of claim 3, wherein the first chip further comprises a semiconductor layer, and the second conductive layer is located above the semiconductor layer.

5. The multi-die packaging structure of claim 1, wherein materials of the insulating dielectric layer comprises at least one of glass, pre-impregnated resin glass fiber cloth, and adhesive film.

6. The multi-die packaging structure of claim 5, wherein the isolation structure further comprises a connection layer located between the insulating dielectric layer and the first conductive layer, for fixedly connecting the insulating dielectric layer and the first conductive layer.

7. The multi-die packaging structure of claim 6, wherein material of the connecting layer comprises a titanium compound; the first conductive layer is a metal plating layer, and the connecting layer is a seed layer of the metal plating layer.

8. The multi-die packaging structure of claim 1, wherein the first conductive layer is a single-layer conductive layer or multiple conductive stacked layers.

9. The multi-die packaging structure of claim 8, wherein the isolation structure further comprises an interlayer isolation layer and an interlayer connection layer,
in the first conductive layer, the interlayer isolation layer and the interlayer connection layer are located between two adjacent conductive stacks.

10. The multi-die packaging structure of claim 1, wherein the isolation structure further comprises a metal coating layer located on the surface of the first conductive layer.

11. The multi-die packaging structure of claim 1, wherein material of the adhesive layer comprises at least one of mounting adhesive, polyimide, and pre-impregnated resin glass fiber cloth, and the isolation structure is fixed to the first die through the adhesive layer.

12. A multi-die packaging structure, comprising: a first die, a second die, and an isolation structure, wherein the isolation structure is electrically connected to the first die and the second die, respectively,
the isolation structure comprises a first isolation structure, a second isolation structure, and an adhesive layer located between the first isolation structure and the second isolation structure,
wherein the first isolation structure comprises:
a first glass substrate;
a first connecting layer, located on the first glass substrate; and
a first conductive layer, located on the first connection layer,
the second isolation structure comprises:
a second glass substrate;
a second connecting layer, located on the second glass substrate; and
a second conductive layer, located on the second connection layer,
the adhesive layer is located between the first glass substrate and the second conductive layer, and is used to fixedly connect the first isolation structure and the second isolation structure,
at least one of the first conductive layer and the second conductive layer forms at least one of an isolation inductor, isolation capacitor, or isolation transformer.

13. The multi-die packaging structure of claim 12, wherein the first conductive layer is a single-layer conductive layer or multiple conductive stacks, and the second conductive layer is a single-layer conductive layer or multiple conductive stacks.

14. The multi-die packaging structure of claim 12, further comprising an interlayer dielectric layer and an interlayer connection layer located between two adjacent conductive stacks.

15. A multi-die packaging structure, comprising:
a first die, a second die, and an isolation structure, wherein the isolation structure is electrically connected to the first die and the second die, respectively,
the isolation structure comprises:
a glass substrate, with opposing first surface and second surface;
a first connecting layer, located on the first surface;
a second connecting layer, located on the second surface;
a first conductive layer, located on the first connection layer; and
a second conductive layer located on the second connection layer,
wherein, at least one of the first conductive layer and the second conductive layer forms at least one of an isolation inductor, isolation capacitor, or isolation transformer.

16. The multi-die packaging structure of claim 15, wherein the first conductive layer is a single-layer conductive layer or multiple conductive stacks, and the second conductive layer is a single-layer conductive layer or multiple conductive stacks.

17. The multi-die packaging structure of claim 15, wherein the interlayer dielectric layer and the interlayer connection layer are located between the two adjacent conductive stacks.

18. The multi-die packaging structure of claim 1, further comprising a packaging frame, wherein the first die and the second die are respectively fixed on the packaging frame.

19. The multi-die packaging structure of claim 18, wherein a solder pad on the packaging structure are electrically connected to the first conductive layer of the isolation structure through wire bonding, or the second die comprises a third conductive layer, which is electrically connected to the first conductive layer of the isolation structure through wire bonding.

20. The multi-die packaging structure of claim 1, further comprising a packaging layer for covering the first die, the second die, and the isolation structure.
